(19) United States
(12) Patent Application Publication
(10) Pub. No.: US 2023/0380025 A1
(43) Pub. Date: Nov. 23, 2023

(54) COMPACT AND LIGHT ELECTROMAGNETIC SHIELDING FOR A HIGH-POWER INDUCTOR

(71) Applicants: ORANO RECYCLAGE, Chatillon (FR); COMMISSARIAT À L'ÉNERGIE ATOMIQUE ET AUX ÉNERGIES ALTERNATIVES, Paris (FR)

(72) Inventors: Etienne Rousset, Cherbourg-En-Contentin (FR); Gilles Quidor, Ranchy (FR); Patrice Brun, Saint-Michel D'Euzet (FR)

(21) Appl. No.: 18/247,912

(22) PCT Filed: Oct. 25, 2021
(86) PCT No.: PCT/FR2021/051871

§ 371 Date: Apr. 5, 2023

(30) Foreign Application Priority Data
Oct. 23, 2020 (FR) 2010884

(51) Int. Cl. H05B 6/36; F27D 11/06; G21F 9/30

(52) U.S. Cl. CPC H05B 6/365; F27D 11/06; G21F 9/302; F27B 14/061

(57) ABSTRACT

The electromagnetic shielding of the inductor comprises a main field-concentrating shielding composed of vertical columns, and the columns are composed of ferromagnetic blocks separated by non-magnetic gaps which contribute to increasing the magnetic reluctance in order to strongly reduce the heat losses. The main shielding is supplemented by an outer conductive casing which confines the residual field that has escaped from the main shielding. The shielding is compact, the mass of ferromagnetic material to be used is modest, autonomous cooling of the main shielding is unnecessary and the electromagnetic coupling between the casing and the main shielding reduces or even eliminates the effects on the electrical characteristics of the equipment.

### DESCRIPTION OF INVENTION

The present invention relates to a shielded electromagnetic inductor, able to operate at high induction frequencies, with high reactive power and possibly in an environment with high ionising radiation, without excluding more general applications. The inductor of the invention is provided with an improved electromagnetic shielding, especially with respect to overall size, mass and preservation of electrical parameters of the load. It can be used in a melting furnace with solid load.

The management of the magnetic field in induction systems has been the subject of some patents and scientific publications. Applications exist on a wide range of scales, from microelectronic components to industrial furnaces of several metres in length. Confinement of the magnetic field by means of a shielding device around the source can be useful to improve electrotechnical performance of the system or to provide immunity to electromagnetic radiation between the system and its external environment. In the latter case, the shielding helps to avoid electromagnetic disturbances and their consequences such as undesirable electromotive forces or heating, electric arcs, electromagnetic interference and electromagnetic compatibility problems between electrical apparatuses as well as risks of disturbance to living organisms. Usual passive electromagnetic shieldings consist of a metal casing or even field concentrators made of high magnetic permeability materials, referred to as ferromagnetic materials (materials capable of attracting and channelling the magnetic field).

Metal casings are mainly used when the electromagnetic radiation is of low power and high frequency. This solution is well adapted to electronic equipment. For devices including an inductor producing a high amplitude magnetic field, this solution creates too much mutual inductance between the inductor and casing, which makes it necessary to keep some distance between these two elements so as not to reduce the efficiency of the inductor and not to overheat the casing or add a new cooling device thereto. The overall size of the shielding with a metal casing can then turn out to be incompatible with integration restrictions.

Field concentrators are used to limit field leakage that is too low frequency for a metal casing (their penetration depth is too great) or to improve the efficiency of an electrical component. For applications operating up to a few tens of kilohertz (for example transformers on the electrical grid, industrial furnaces for metal smelting), concentrators traditionally used consist of a laminate of rolled iron and electrical insulator. For higher frequency applications, solid ferromagnetic parts are used. In this case, various difficulties are encountered in the design. First of all, heat losses in the usual field concentrators are very high for use at high frequency and high reactive power, such as in the area mainly contemplated (above 100 kHz, and in the order of 300 kHz; above 1 Mvar, and in the order of 12 Mvar). These heat losses can be amplified by magnetic resonance phenomena likely to occur in common ferromagnetic materials such as soft ferrites, obtained by moulding and compacting iron oxide or other metal powders, when these parts reach centimetric dimensions. Ferrites adapted to frequency ranges above 100 kHz (based on Zn and Mn, Ni or Mg, for example) are moreover delicate materials to machine because of their great hardness and fragility. Their integration in large or complex geometric equipment is therefore particularly difficult. Soft ferrites are therefore mainly used in generic formats as absorbers of electromagnetic interference in cables or in small transformers and inductors in electronic circuits, and much less in induction heating systems.

Other contemplatable ferromagnetic materials are composites, referred to as bonded ferrites, which include an organic electrically insulating binder (for example PTFE) between iron powder grains. The value of using such materials for induction heating is well documented. They have the great advantage of being easier to machine.

However, bonded ferrites dissipate more heat loss than soft ferrites and are not compatible with strong ionising radiation because the insulator they contain is an organic one.

Finally, a proper confinement of the magnetic field by field concentrators would imply, in the applications particularly contemplated here, a quite excessive mass and overall size, because of, among other things, the quantity to be implemented or the need to cool them by dedicated cooling fluid circuits. On the other hand, inductors provided with usual field concentrators are constructed with a coiling consisting of several turns in series, each of which goes around the load to be heated. For high power (>1 Mvar reactive power) and high frequency (>100 kHz) applications, the series turns impose too high a voltage, which makes it necessary to use a single turn (coiling having one turn), which can be composed of several inductor parallel supplied strands. The problem with a parallel connection is that the current distribution is preferentially on the peripheral regions or strands, which yields non-uniform heating in the inductor, and the radiated magnetic field and the induction in the load are also less uniform. If field concentrators are installed near a parallel-strand inductor, these heterogeneities are intensified. For this reason, field concentrators are mainly adapted to inductors with series turns.

A final difficulty to consider is that field concentrators such as metal casings placed in proximity to the inductor modify electrical parameters of the load observed by the power source, which may make it impossible to integrate a shielding onto an existing equipment without making significant modifications to the generator or electrical conductors.

U.S. Pat. No. 5,197,081 A describes an induction furnace with an electromagnetic shielding for deviating field lines that would be otherwise strongly curved outwardly and reach an outer casing, developing induced currents and heat losses therein. The shielding consists of loops with a laminated structure, composed of ferromagnetic layers alternating with insulating layers; all these layers loop on themselves, the former deflecting the field lines and the latter preventing excessive heating in the shielding. The field does not reach the outer casing, which therefore does not contribute to the shielding, and no cooling of the ferromagnetic shielding is necessary. However, the laminated structure is not suitable for high power and high frequency.

U.S. Pat. No. 5,588,019 A describes an induction furnace in which the inductor coiling is completely encased (on the radially outward side) by a DC field concentrator made of a composite of iron powder and a bonding polymer. The utilisation of these materials is not appreciated in the invention because of the excessive losses they cause at high power levels. Cooling, which is avoided as far as possible in the invention, is provided for this shielding. There is no outer casing but a very airy assembly structure.

JP H8 155 591 A describes an induction furnace provided with a shielding which may be made of ferrite and split into sectors in the angular direction of the furnace, that is it is composed of columns separated from each other and each embracing a circumference portion of the furnace; this arrangement prevents induced currents from forming in the shielding. Such continuous column devices, which are intended to capture the maximum magnetic field, are inherently incompatible with the application particularly contemplated here because they would result in too high a magnetic flow, and hence heat loss, in the shielding. Here too there does not appear to be a continuous outer casing around the furnace and field concentrator, but a simple assembly structure or attachment shoe. The main technical problem solved by this document is to stop the magnetic field in the axial direction, by virtue of flat circular bottom and top conductive plates on which the ends of the field concentrator rest, so as not to let a long conduit serving as a crucible deviate the field lines away from the heating place.

The purpose of the invention is to provide confinement of a magnetic field which may be produced by a high power inductor operating at a high frequency with a device:
providing a high level of confinement for an inductive field that may be a few tenths of a milliTesla to a few milliTesla at a frequency that may be in the range of 100 kHz to 1 MHz, for example 300 kHz,
having a controlled temperature without an additional cooling circuit,
compact and limited in mass,
limiting the shift in electrical parameters with respect to a shielding-free configuration, so that the shielding can be integrated into an existing furnace equipment with little or no modification to the power source,
that can be manufactured using conventional industrial means,
maintaining good induction homogeneity in the load volume, especially in the longitudinal direction of the inductor,
having a lifetime of several years with intensive industrial use, with little or no maintenance and in an environment with high radioactivity.

A particular application targeted by the invention is cold crucible induction heating for vitrification of nuclear waste.

In a general form, the invention relates to a shielded electromagnetic inductor, comprising an inductor arranged in front of a load to be heated by electromagnetic induction and composed of at least one conductive turn, where current flows in a turn length direction, and an electromagnetic shielding comprising a magnetic field concentrator disposed in front of the inductor with the inductor located between said concentrator and the load, said concentrator comprising ferromagnetic columns whose main direction of elongation coincides with a direction of a main component of magnetic field lines propagated by the inductor from a side facing the concentrator, the columns being separated from each other by an electrically insulating medium and each embracing a portion of turn length of the inductor, characterised in that the columns are composed of ferromagnetic elements succeeding each other in said direction of extension of the columns and separated by electrically insulating gaps, of lower magnetic permeability and shorter length than the ferromagnetic elements in said direction of elongation, and in that the electromagnetic shielding further comprises an electrically conductive casing, the field concentrator being located between the casing and the inductor.

These gaps can consist of either an electrically insulating material or an air space.

It is set out that the term “ferromagnetic” covers the property of materials to attract the magnetic field, that is with a relative magnetic permeability greater than 1.

With respect to some known designs where the field concentrator is split into sectors parallel to the field lines, the design of the invention is also split into sectors perpendicular to the field lines, with two main effects. The first is that, with respect to conventional designs where the field concentrators are continuous in line with the magnetic field lines, the magnetic flow captured by the columns is lower, so that heat losses are significantly reduced in the concentrator and cooling is not necessarily required or can be accomplished without an additional fluid circulation device, as will be discussed below. The second is that the residual inductive coupling with the conductive outer casing is increased, in a way that reduces the disturbing effect of the shielding on the electrical parameters of the equipment as observed from the power source when the shielding is to be added to existing equipment, and thus allows the shielding to be added without significant modification elsewhere in the equipment.

Ferromagnetic elements are advantageously of soft ferrite, without polymeric binder or other composite material. Machining solid, block-shaped or tile-shaped ferrite elements suitable for high power ratings, such as those based on Mn and Zn, which is considered difficult, is however feasible under good conditions by water jet cutting.

The shielding comprises an electrically conductive casing disposed in front of the ferromagnetic columns on the side opposite to the inductor. The main shielding provided by the field concentrator columns is then reinforced by an electromagnetic shielding which stops the residual field that has escaped the main ferromagnetic shielding, and contributes to neutralising the overall effect of the shielding on the electrical parameters of the equipment. The thickness of the casing is much greater than the characteristic penetration depth of the field, so that the magnetic field that can pass through the casing is completely negligible. Since induced currents in the casing are moderate by virtue of the low residual field, and since heat losses in and out of the main shielding are reduced by virtue of the construction split into sectors through the gaps, the casing can be close to, but not in electrical contact with, the ferromagnetic columns. The overall size of the device is reduced without the need for cooling and the risk of overheating is eliminated.

By virtue of the antagonistic effects on the load inductance and load resistance of the two components of the combined shielding, it is advantageous, and easy to obtain, that these components are designed so that the resistance and inductance parameters of the equipment as observed from the power supply source have values which differ by less than ±10%, for example, from the respective values of said parameters which would be found in the absence of the shielding.

In a particularly contemplated embodiment or application of the invention, the inductor has a rotational shape about the load and about an axis (generally vertical), so that the direction of elongation of the columns coincides with the direction of the axis and the electrically conductive shroud comprises a portion which surrounds the field concentrator. Other configurations of the furnace are possible, one of which will be briefly described for this text.

Advantageously, the thickness of the gaps is adjusted so as to increase the total magnetic reluctance of the shielding by a factor of 20 to 80 with respect to a configuration without gaps, and thus to take full advantage of the effects of vertical splitting into sectors. The ideal thickness of the gaps to provide such an improvement depends on the cross-section of the columns and ferromagnetic blocks.

At least for the high power and high frequency range, the inductor will generally be a single turn inductor composed of strands electrically connected in parallel.

In this case, an arrangement may be preferred in which the strands are composed of vertically tilted portions, being alternately descending and ascending and distributed in two circular, concentric plies extending at identical heights along the axis, a first of the plies comprising all the ascending portions and a second of the plies all the descending portions: such a construction of the inductor reduces edge effects, that is current intensity differences between the strands and induction irregularities in height, especially at the high and low ends of the inductor. A more advantageous configuration, with respect to ferrite losses and shift in electrical parameter, is to have several gaps distributed along the column rather than a single wider gap. It may be advantageous to apply, for such single-turn inductors, an arrangement where the ferromagnetic blocks each extend in front of only one of the inductor strands (or only one of the descending or ascending portions of the radially outermost one of the plies, if the turn is composed of said portions in said concentric plies), in order to limit risks of electrical conduction between adjacent strands, especially in the constructions detailed below where the blocks are connected to the inductor.

A remarkable construction, capable of simplifying the manufacture of the furnace with good accuracy of its dimensions, as well as good quality of operation, appears if at least some of the following characteristics are present:

The ferrites (ferromagnetic elements) are mechanically linked to the inductor in order to benefit from its mechanical support and possible cooling source. The supports are then advantageously thermally conductive. The ferrites benefit from the cooling of the inductor and can more easily do without their own cooling device.

The ferrites are held in place by adhesive or by an attachment device such as screws, clips or the like.

A layer of thermally conductive binder is recommended on the ferrite surfaces in contact with the cooling source.

An intermediate layer of electrically insulating material is strongly recommended (but not mandatory in all cases) between the ferrites and any other electrically conductive part resting on the ferrites, in particular parts subject to high electromotive forces such as the inductor, in order to significantly reduce Joule losses in the ferrites and to avoid the risk of short circuits through the ferrites. The elements holding the ferrites that do not contribute to the cooling process, but which rest on the ferrites, such as screws or other attachment systems, are preferably made entirely of electrically insulating material.

Some epoxy adhesives make it possible to satisfy both of the above points simultaneously and are only slightly degraded by ionising radiation.

So-called adaptive parts of a material with high thermal conductivity, such as metal, can be inserted between the ferrites and the inductor if proper heat conduction is desired. However, another function of the adaptive parts is to facilitate connection of the ferromagnetic elements to the inductor even if their shapes are different, for example if the ferromagnetic elements are flat while the inductor is rotationally shaped. The adaptive parts may have a first side with a curvature identical to the inductor and a second side, opposite to the first side, on which at least one ferromagnetic element is installed and which has a curvature identical to said ferromagnetic elements installed.

The adaptive parts can be held to the inductor by a thermally conductive binder such as solder (if there are metal supports) or the aforementioned epoxy adhesives or by other means of attachment such as screws, bolts, studs, clips or the like.

An advantageous construction characteristic is that the supports have less extension than the ferromagnetic elements in the direction of elongation of the columns, and the ferromagnetic elements have end edges in the direction of elongation which are clear of the supports. This applies especially if the supports include electrically conductive adaptive parts, in order to avoid losses of electromagnetic energy here as well.

Sharp corners on the ferromagnetic elements are to be avoided, in order to further avoid electromagnetic energy losses due to the spike effect. In a usual case where the elements will be in the form of flat quadrangular blocks or tiles, it may be advantageous to chamfer them at least at some corners of the quadrangle.

One advantageous aspect of the invention is that the conductive casing can be brought very close to the field concentrator. If this distance is made very small, however, it may be advantageous to have a layer of electrical insulator between the conductive casing and the field concentrator.

An important advantage of the invention is the efficiency and lightness of the electromagnetic shielding, to the extent that it is contemplatable that the shielding has a lower mass than the inductor.

Another aspect of the invention is a particularly contemplated—but not exclusive—use of this shielded electromagnetic inductor in a furnace for vitrifying nuclear waste.

A particular and purely illustrative embodiment of the invention will now be set out in detail, in order to grasp the various aspects, characteristics and advantages thereof, by means of the following figures:

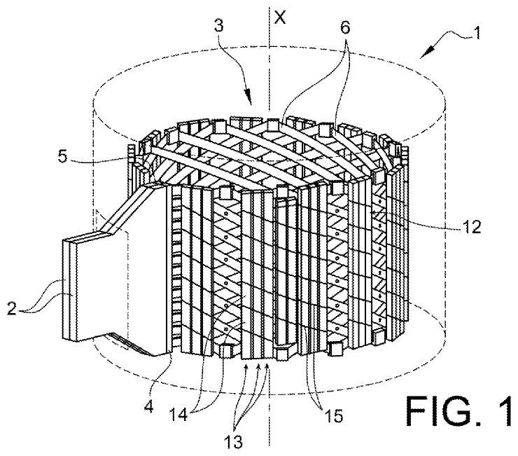

FIG. 1: an overall view of the shielded inductor device;

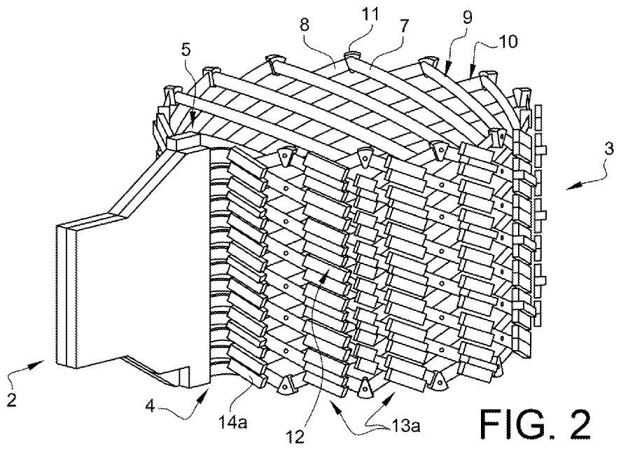

FIG. 2: first embodiment of the ferromagnetic field concentrator;

FIG. 3: second embodiment;

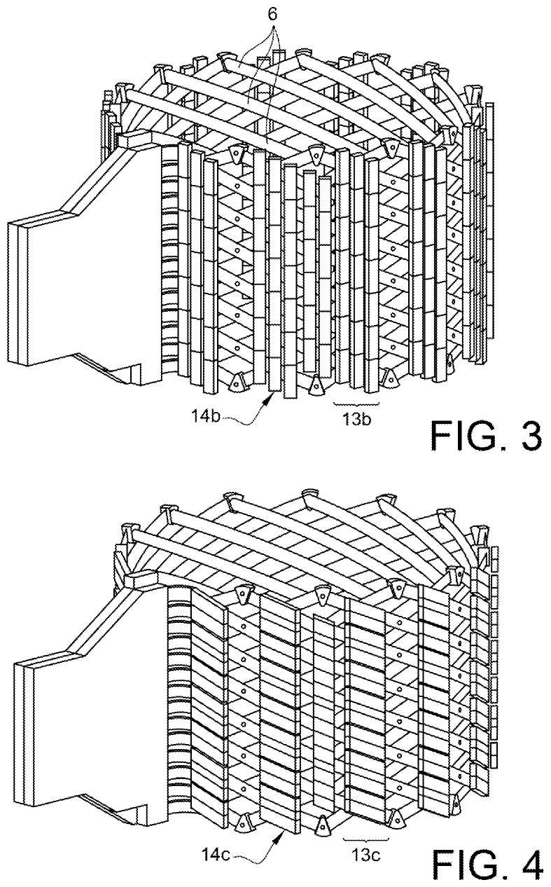

FIG. 4: third embodiment;

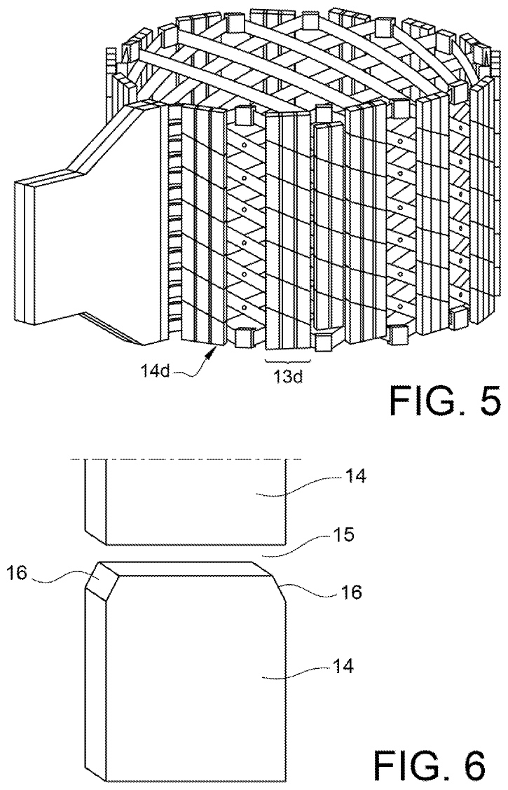

FIG. 5: fourth embodiment;

FIG. 6: embodiment detail of the ferromagnetic elements;

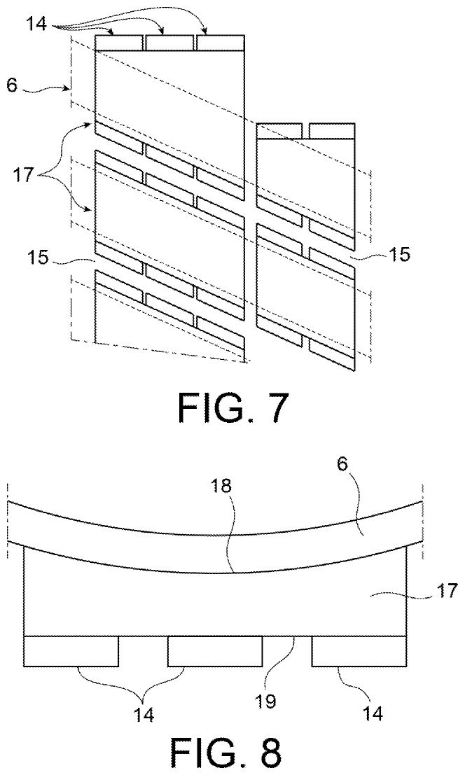

FIG. 7: front view of the supports for the ferromagnetic elements;

FIG. 8: top view of one of the supports;

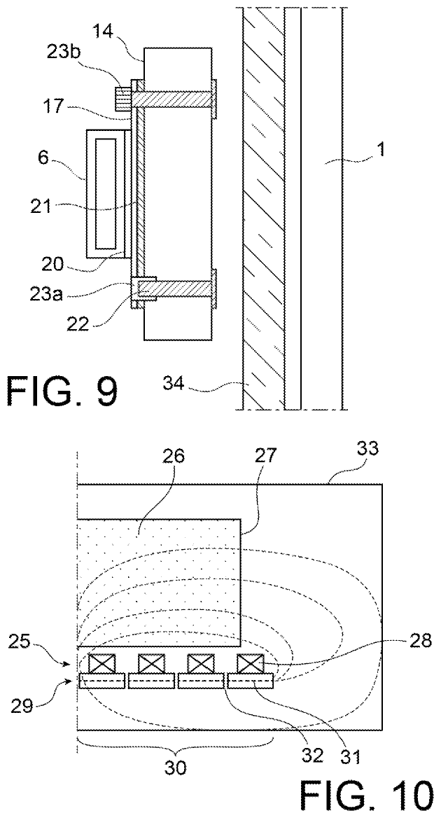

FIG. 9: partial vertical cross-section view of the inductor with the shielding;

FIG. 10: view of another possible embodiment of the shielded inductor;

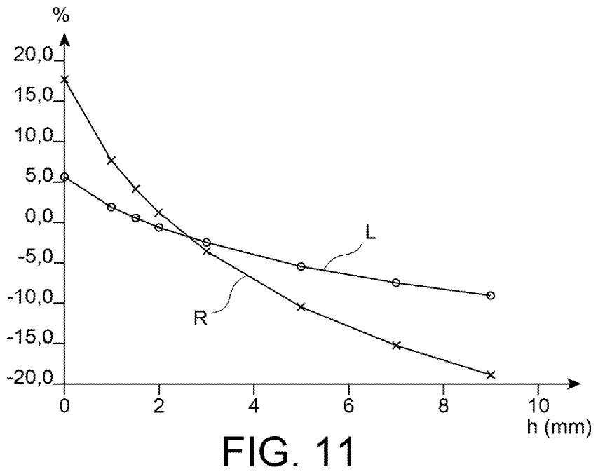

FIG. 11: electrical parameter diagram;

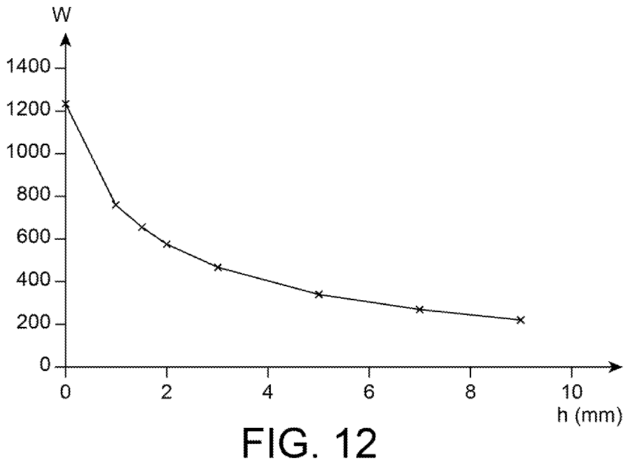

FIG. 12: heat loss diagram.

FIG. 1 illustrates the shielded inductor seen from outside. Its general shape is rotationally symmetrical and cylindrical with a vertical axis X and upwardly open in this embodiment, and it is surrounded by an electrically conductive metal outer casing 1 which is used for the electromagnetic shielding. The outer casing 1 comprises an almost continuous circumferential wall, from which, however, inlet and outlet connections 2 emerge, through which an inductor 3 is supplied with electricity and cooling fluid. It may be supplemented by bottom and top walls to further isolate the inductor from outside. It may be made of metal, copper or aluminium alloy. The inductor 3 is better visible in the following FIGS. 2 to 5, which will be now discussed. It is formed by a single turn of complex shape which surrounds, for example, the load to be heated, which may be contained in a crucible, which may itself be a so-called cold crucible. Cold crucibles, used for the vitrification of nuclear waste, which is a contemplated application of the invention, are cooled by an inner liquid circulation and produce a surface solidification, capable of protecting them from corrosion, of the load in contact with them. The inlet and outlet connections 2 lead to two collectors 4 and 5 which are elongate conductive blades, close to each other and which are the ends of the inductor 3. The conductive turn is composed of conductive strands 6, all of which are connected to the collectors 4 and 5 and which are therefore electrically connected in parallel, making a single turn around the furnace. Each strand 6 is zigzag-shaped and essentially composed of so-called ascending portions 7 alternating with so-called descending portions 8 with opposite vertical tilts. All the ascending 7 and descending 8 portions extend from the lowest to the highest level of the inductor 3. The ascending portions 7 thus cross the descending portions 8, but without touching them, since they extend in separate concentric cylindrical plies, the (conventionally) ascending portions 7 in an inner ply 9 and the (conventionally) descending portions 8 in an outer ply 10. Indeed, the strands 6 still comprise short, radially directed connections 11, which connect each ascending or descending portion to the adjacent portions of the strand 6. This arrangement, already known from document WO 2007/031564 A1, is preferred here because it reduces induction heterogeneities in height and especially current concentrations at the upper and lower edges of the inductor 3, referred to here as edge effects. Finally, the collectors 4 and 5 as well as the strands 6 are hollow and have a cooling fluid flowing therethrough, similar to that described in this document.

The furnace comprises a main electromagnetic shielding which is a magnetic field concentrator 12 and which extends, with a generally annular shape, between the inductor 3, radially inwardly of it, and the outer casing 1, radially outwardly of it. It is composed of vertical columns 13 (erected in the direction of the axis X) each embracing a circumferential sector of the furnace but separated from each other and formed of ferromagnetic elements which are here parallelepipedic ferrite blocks 14 (also designated 14a, 14b, 14c or 14d in FIGS. 2 to 5), or quadrangular flat tiles, superimposed in the vertical direction, but separated by electrically insulating and non-magnetic gaps 15 interposed between them. The gaps 15 may be physical gaps maintaining continuity of the columns 13, or they may be empty spaces, which is permitted if the blocks 14 are supported independently of each other. The function of the field concentrator 12 is to channel magnetic field lines external to the inductor 3 to concentrate the magnetic field within a reduced perimeter, maintain or increase the currents induced in the load to be heated and maintain or enhance the thermal efficiency of the furnace, while partially limiting the inductive coupling with the peripheral casing 1 which finishes blocking outwardly the magnetic field leakages. Together with the casing 1, it forms the overall electromagnetic shielding of the equipment. The ferromagnetic blocks 14 can be up to a few centimetres high, a few degrees of angular extension (preferably less than 15°), and the gaps 15 a few tenths of a millimetre to a few millimetres high. The extension of the ferromagnetic blocks 14 in the radial direction is restricted to facilitate their cooling by the inductor 3 in a manner indicated below, whereas the ferromagnetic blocks 14 are devoid of a cooling fluid circuit specifically associated therewith. Their extension in angular direction is also restricted, in order to limit magnetic resonances. In addition, it is recommended that each ferromagnetic block 14 extends in front of a single strand 6, in order to limit risks of electrical conduction in the field concentrator 12 between adjacent strands 6; with the inductor 3 composed of intersecting zigzagging portions, this principle is applied by making each ferromagnetic block 14 extend in front of a single portion (here called the descending portion 8) of the external ply 10, which is contiguous thereto.

Several alternative embodiments can then be contemplated, considering that the cross-section and the number of columns 13 can be varied, in order to optimise channelling of the flux and the magnetic resonance effects and that the ends of the ferromagnetic blocks 14 can be adjusted in different ways, depending on the desired ease of assembly and optimisation of the ferrite mass. In FIG. 2, the ferromagnetic blocks 14a are shaped like parallelepipeds, or rectangular tiles, tilted like the strands 6, thereby producing columns 13a with irregular side edges in broken lines; in FIG. 3, the ferromagnetic blocks 14b are still rectangular tiles, but with their vertical side, a smaller angular extension than in the previous case, but a greater vertical extension; each of the columns 13b is then composed of several juxtaposed stacks of ferromagnetic blocks 14b, and the upper edges of these columns 13b are stepped. The arrangement of FIG. 4 is similar to that of FIG. 2, except that the rectangular tiles are replaced by trapezoidal tiles, so that the magnetic blocks 14c result in columns 13c whose lateral sides are vertical and regular. Finally, the arrangement of FIG. 5 is similar to that of FIG. 3, except that here too the rectangular tiles are replaced by trapezoidal tiles whose upper and lower edges are tilted similarly to those of the strands 6 and at right angles to the lateral sides at the ends of the columns 13d, giving rectilinear edges to the columns 13d. In each of these arrangements, it may be contemplated that the sharp corners of the ferromagnetic blocks 14 may be broken by chamfering or filleting between sides, as spike effects, resulting in high magnetic field concentrations and localised losses, are likely to occur at these places. One possible embodiment is represented in FIG. 6, where the chamfers are marked as 16.

It is contemplated that the ferromagnetic blocks will be supported by the inductor. The support may possibly be direct, if the inductor strands 6 and the ferromagnetic blocks 14 have complementary shaped faces allowing them to be joined directly by adhesive or otherwise. However, this can cause significant problems, because of the difficulty of shaping ferrites to complex shapes or of replacing conventional inductors of simple, regular rotational shape with others. If a direct support is excluded, the strands 6 could support the ferromagnetic blocks 14 by means of supports 17 (not represented in the previous figures) summarily represented in FIG. 7, in the form of plates, which, according to FIG. 8, will be shape-adaptive parts between the strands 6 and the ferromagnetic blocks 14 and will have an irregularly shaped cross-section, an internal side 18 having a curvature similar to that of the strands 6 and an external side 19 being flat if the ferromagnetic blocks 14 are flat tiles, or, more generally, having a curvature identical to that of the ferromagnetic blocks 14. Such an arrangement allows the strands 6 and the ferromagnetic blocks 14 to be pressed against the supports 17 and thus facilitates cohesion of the whole. FIG. 7 shows that the vertical extension of the supports 17 is advantageously less than that of the ferromagnetic blocks 14 so that the ferromagnetic blocks 14 project from the supports 17 at their upper and lower ends and so that couplings of the magnetic field with the supports are avoided in the place of the gaps 15 and at the ends of the columns. The supports 17 therefore advantageously have tilted upper and lower edges, like the corresponding and adjacent edges of the ferromagnetic blocks 14.

The supports 17, as well as the other components of the assemblies for supporting ferromagnetic blocks 14 by the strands 6, are preferably designed to allow thermal conduction between the strands 6 and the ferromagnetic blocks 14, but instead electrical insulation, in order both to promote cooling of the ferromagnetic blocks 14 by the cooling fluid circulating in the strands 6 and to avoid additional Joule losses in the ferromagnetic blocks 14 through the flow of electric current with the strands 6 or any other electrically conductive element subjected to electromotive forces. A schematic device, represented in FIG. 9, may further comprise a solder 20, or another thermal and mechanical binder, between the internal side 18 of the supports 17 and the strands 6, an epoxy adhesive 21 or another thermal and thus preferably electrically insulating binder between the external side 19 of the support 17 and the ferromagnetic blocks 14, and screws 22, bearing on the external face of the ferromagnetic blocks 14, extending along their lateral faces and bolted into bosses 23a of the supports 17 or nuts 23b located behind them, on the inductor 12 side. Holding ferromagnetic blocks 14 in place is thereby achieved, the retention in the vertical position being ensured mainly by the adhesion of the linking layer 21. Alternatively, the screws 22 could pass through the ferromagnetic blocks 14 to ensure this function too. Other types of support could be considered to perform these functions of holding in place. Alternatively, the device could include supports not represented provided with lower or lateral edges allowing the ferromagnetic blocks 14 to be placed on them and thus replacing at least some of the screws 22 or dispensing with the adhesive property of the linking layer 21. However, the device of FIG. 9 has the advantage of reducing the area facing the supports 17 and the ferromagnetic blocks 14 and of constructing more easily supports 17 of metal, thus avoiding electrical contact with the ferromagnetic blocks 14 through the connecting layer 21 easily laid.

FIG. 9 further shows that a layered electrical insulating material 34 can be interposed between the field concentrator 12 and the outer casing 1, if they are close to each other, since sufficient channelling of the magnetic field into the ferromagnetic blocks 14 can allow such a close proximity, advantageous for reducing the overall size of the device, provided that electrical insulation is maintained between the two shielding components.

The invention could be implemented in other ways, especially with non-cylindrical inductors. FIG. 10 represents such an alternative, where a flat inductor replaces the previous inductor and is located under the load to be heated 26, placed as before in a cylindrical crucible 27 which may be a cold crucible. The strands 28 of the inductor 25 can be parallel to each other or can be placed as in the previously contemplated embodiment, developing the plies on a plane. The field concentrator 29 is made up of columns 30 perpendicular to the overall direction of the strands 28, and they are composed, as before, of ferromagnetic blocks 31, each of which can be associated with one of the strands 28 facing it, and separated by gaps 32. The principles of construction of the field concentrator 29 are therefore applicable to such inductors at will. The outer casing 33 extends under the inductor 25 and the field concentrator 29, preferably all around the device and over the crucible 27. Magnetic field lines have been represented which remain enclosed within the casing 33 or are channelled through the ferrite columns 30.

Some benefits of the invention are as follows:
improved confinement of the magnetic field, reducing the field amplitude outside the shielding by up to a factor of 40 with respect to an arrangement with ferromagnetic columns of the same mass and arrangement but continuous in the alignment of the magnetic field lines, free of the gaps 15, and in the absence of an outer casing;
total shielding mass reduced by a factor of up to 4 with respect to a shielding exclusively composed of ferromagnetic material with equal attenuation of magnetic field leakage outwardly;
radial overall size divided by a factor of 2 with respect to a shielding with only a metal casing without any particular cooling device;
less than ±10% shift in electrical parameters observed from the inductor power supply with respect to an unshielded configuration;
an imbalance of about ±20% in the currents flowing through the individual strands of the inductor provided with the shielding, instead of about ±97% for a single turn arrangement with parallel, non-interlaced strands.

This will be illustrated in the final figures. FIG. 11 illustrates the effect of a plausible embodiment of the invention on the electrical parameters of resistance and inductance of the device as observed from the power supply to the inductor (operating, for example, at 3000 V and 300 kHz, for an active power of 300 kW in an inductor 0.8 m in diameter and 0.6 m high, composed of fourteen interwoven strands 6 in parallel supply and a ferrite arrangement as described hereinabove having a relative magnetic permeability of 4000), in percentage deviations from the parameters valid for the same embodiment without shielding, based on the height of the separations between the ferromagnetic blocks 14, that is the thickness of the gaps 15, expressed in millimetres in the abscissa. A range of values of interest for applying the invention based on the criterion of maintaining the electrical parameters of the equipment extends from about 1 mm to 4 mm, between which the resistance R varies between ±8% maximum, and the inductance L varies from +2% to −4% maximum. The result can be compared to the one that can be inferred from FIG. 12, which indicates the course of the heat losses in the ferrite assembly in watts based on the same thickness parameter of the gaps 15. The decrease in these losses is immediate as soon as gaps 15 are installed, and greater the greater their thickness; however, the thickness increments have less and less effect as the thicknesses to which they are added are greater. In this embodiment, a loss reduction of about 40% is already achieved for thicknesses of 1 mm, and a reduction of about 70% for thicknesses of 4 mm. The range of values stated above can be considered satisfactory on the basis of this second criterion. The physical phenomenon controlled and adjusted by virtue of the presence of the gaps 15 is a variation in the magnetic reluctance of the ferrite columns 13, here vertical, that is their capacity to capture magnetic flux. An approximation of the increase in reluctance in a column can be expressed in absolute values (units in the international system) as: deltaR=1/μ*e/S*nEsp where: deltaR, increase in reluctance; μ, magnetic permeability in the gap 15; e: dimension of the gap 15 in the direction of the field lines; S, cross-sectional area of the field lines in the column 13; nEsp, number of gaps 15 along the column 13. The overall reluctance of the shielding can also be estimated using an expression comprising the unit reluctances of each component through which the magnetic field lines pass, formulated according to the usual laws of calculating reluctances in magnetic circuits.

What is claimed is:

1. A shielded electromagnetic inductor, comprising
an inductor arranged in front of a load to be heated by electromagnetic induction and composed of at least one conductive turn, where current flows in a turn length direction, and
an electromagnetic shielding comprising a magnetic field concentrator arranged in front of the inductor, with the inductor between said field concentrator and the load, said concentrator comprising ferromagnetic columns,
a main direction of elongation of which coincides with a direction of a main component of magnetic field lines propagated by the inductor on a side oriented to the field concentrator,
the columns being separated from each other by an electrically insulating medium and each embracing a portion of turn length of the inductor,
wherein the columns are composed of ferromagnetic elements succeeding each other in said direction of elongation and separated by electrically insulating gaps, having lower magnetic permeability and shorter length than the ferromagnetic elements in said direction of elongation, and
wherein the electromagnetic shielding further comprises an electrically conductive casing, the field concentrator being located between said casing and the inductor.

2. The shielded electromagnetic inductor according to claim 1, wherein the ferromagnetic elements are of ferrite.

3. The shielded electromagnetic inductor according to claim 1, wherein the inductor has a rotational shape about the load and about an axis, the direction of elongation of the columns coincides with the direction of the axis, and the electrically conductive casing comprises a portion with a rotational shape about the axis, which surrounds the field concentrator.

4. The shielded electromagnetic inductor according to claim 1, wherein said gaps are dimensioned so as to increase the total reluctance of the shielding by a factor of 20 to 80.

5. The shielded electromagnetic inductor according to claim 1, wherein the inductor is a single turn inductor and the turn is composed of electrically parallel supplied strands.

6. The shielded electromagnetic inductor according to claim 3, wherein the inductor is a single turn inductor and the turn is composed of electrically parallel supplied strands and the strands are composed of portions tilted in the direction of the axis, alternately descending and ascending and distributed in two circular, concentric plies extending at identical heights along the axis, a first of the plies comprising all the ascending portions and a second of the plies all the descending portions.

7. The shielded electromagnetic inductor according to claim 5, wherein the ferromagnetic elements each extend in front of only one of the strands of the inductor, or only one of the descending or ascending portions of that one of the plies which is radially outermost if the turn is composed of said portions in said concentric plies.

8. The shielded electromagnetic inductor according to claim 1, wherein the inductor is cooled by an inner fluid circulation.

9. The shielded electromagnetic inductor according to claim 1, wherein the ferromagnetic elements are mounted to the inductor by support linkages.

10. The shielded electromagnetic inductor according to claim 8, wherein the ferromagnetic elements are mounted to the inductor by support linkages and the support linkages are overall thermally conductive and electrically insulating between the ferromagnetic elements and the inductor, and the ferromagnetic elements are devoid of a particular cooling fluid circuit.

11. The shielded electromagnetic inductor according to claim 10, wherein the support linkages each comprise an adaptive part, a first side of which has a curvature identical to the inductor and is connected to the inductor through a linking layer, and a second side, opposite to the first side, on which at least one ferromagnetic element is installed and which has a curvature identical to said at least one ferromagnetic element.

12. The shielded electromagnetic inductor according to claim 11, wherein said installed ferromagnetic element is linked to the adaptive parts through a second linking layer.

13. The shielded electromagnetic inductor according to claim 11, wherein the support linkages comprise screws for attaching the ferromagnetic elements to the adaptive part.

14. The shielded electromagnetic inductor according to claim 10, wherein the supports have less extension than the ferromagnetic elements in said direction of elongation, and the ferromagnetic elements have end edges in the direction of elongation that are clear of the supports.

15. The shielded electromagnetic inductor according to claim 1, wherein the ferromagnetic elements are blocks or tiles in the form of flat quadrangles, chamfered or provided with fillets at least at some corners of the quadrangle.

16. The shielded electromagnetic inductor according to claim 1, wherein the field concentrator is separated from the conductive casing through a layer of electrical insulator.

17. Use of the shielded electromagnetic inductor according to claim 1 in a furnace for vitrifying nuclear waste.
